(19) United States
(12) Patent Application Publication
(10) Pub. No.: US 2018/0090227 A1
(43) Pub. Date: Mar. 29, 2018

(54) SEMICONDUCTOR MEMORY DEVICE AND OPERATING METHOD THEREOF

(71) Applicant: SK hynix Inc., Gyeonggi-do (KR)

(72) Inventors: Dong-Beom LEE, Gyeonggi-do (KR); Tae-Sik YUN, Seoul (KR)

(21) Appl. No.: 15/603,537

(22) Filed: May 24, 2017

(30) Foreign Application Priority Data
Sep. 26, 2016 (KR) 10-2016-0122922

(51) Int. Cl. G11C 29/00; G11C 7/22; G11C 7/12; G11C 7/10; G11C 8/10

(52) U.S. Cl. CPC G11C 29/787; G11C 7/22; G11C 8/10; G11C 7/10; G11C 7/12

(57) ABSTRACT

A semiconductor memory device includes: a memory array region including normal memory cells and redundant memory cells; a fuse circuit including fuse cells for programming repair addresses, outputting fuse data including the programmed repair addresses and fuse enable signals in response to a boot-up signal; a fuse information storage including N latch circuits for storing the fuse data, wherein each of the N latch circuits drives fuse lines assigned from N fuse lines based on the fuse enable signals and a comparison result of the corresponding repair addresses and an input address; and a repair control circuit generating a repair activation signal and an M-bit repair control signal based on signals of the N fuse lines, and outputting the M-bit repair control signal to multiple address lines by selectively mapping the M-bit repair control signal to some bits of the input address, based on the repair activation signal.

### CROSS-REFERENCE TO RELATED APPLICATIONS

The present application claims priority to Korean Patent Application No. 10-2016-0122922, filed on Sep. 26, 2016, which is incorporated herein by reference in its entirety.

### BACKGROUND

### 1. Field

Exemplary embodiments of the present invention relate to a semiconductor designing technology, and more particularly, to a semiconductor memory device capable of performing a rep operation, and an operating method thereof.

### 2. Description of the Related Art

Generally, a semiconductor memory device such as a Double Data Rate Synchronous Dynamic Random Access Memory (DDR SDRAM) includes a plurality of memory cells. As fabrication technology progresses, the degree of integration is raised, which further increases the number of memory cells. If a defect occurs in even one among the plurality of the memory cells, the semiconductor memory device including the defective memory cell may malfunction. Since the semiconductor memory device including the defective memory cell is not capable of performing a desired operation, the semiconductor memory device has to be discarded.

However, as semiconductor memory device fabrication technology advances, the probability is likely that defects may occur only in a small quantity of memory cells. Thus, it is very inefficient in terms of the production yield to discard the semiconductor memory device due to the minute quantity of possible defects.

To address the problem, a semiconductor memory device may additionally include a redundant memory cell for repairing a defective normal memory cell which is referred to as ‘a repair target memory cell’, along with normal memory cells. Furthermore, the semiconductor memory device may include a redundancy control circuit which senses the repair target memory cell through a test in advance. When a request for accessing the memory cell is received, the redundancy control circuit switches the access to the redundant memory cell instead of the repair target memory cell. Therefore, when an address which is hereafter referred to as ‘a repair address’, corresponding to the repair target memory cell is inputted, the semiconductor memory device may perform an operation which is hereafter referred to as ‘a repair operation’ for accessing the redundant memory cell, not the repair target memory cell. Therefore, through the operation the semiconductor memory device is guaranteed to perform a normal operation.

The semiconductor memory device requires not only the redundant memory cell and the redundancy control circuit but also other circuits in order to perform the repair operation. The other circuits may include a fuse circuit for programming repair information of a row or column address and a latch circuit for storing a data programmed in the fuse circuit. The fuse circuit may include a plurality of fuse cells for programming a repair address. The latch circuit may receive and store the data programmed in the fuse circuit during a boot-up operation. After the boot-up operation, the semiconductor memory device may perform the repair operation based on the data stored in the latch circuit.

Furthermore, the semiconductor memory device may be largely divided into a core region and a peripheral circuit region. The core region may include a plurality of memory banks, each of which includes a plurality of memory cells for storing data. The peripheral circuit region may include subsidiary circuits for controlling and setting the operations of the core region. Generally, normal memory cells, redundant memory cells, the redundancy control circuit, the fuse circuit and the latch circuit are disposed in the core region.

As the capacity of semiconductor memory devices is increasing, the number of unit latches that are disposed in the inside of the fuse circuit and the latch circuit is increasing as well. This leads to an increase in the area occupied by the fuse circuit and the latch circuit. Moreover, since the fuse circuit and the latch circuit are disposed in the core region, which has an available area that is relatively smaller than that of the peripheral circuit region, it becomes difficult to realize a high degree of integration in the semiconductor memory device.

### SUMMARY

Embodiments of the present invention are directed to a semiconductor memory device in which a fuse circuit and a fuse latch circuit for programming repair information are distributively disposed in a peripheral circuit region and the repair information is transferred through an existing address line.

In accordance with an embodiment of the present invention, a semiconductor memory device includes: a memory array region including normal memory cells and redundant memory cells which replace repair target memory cells; a fuse circuit including fuse cells for programming repair addresses of the repair target memory cells, suitable for outputting fuse data including the programmed repair addresses and fuse enable signals indicating whether or not the repair addresses are valid, in response to a boot-up signal; a fuse information storage including N latch circuits for storing the fuse data, wherein each of the N latch circuits drives fuse lines assigned from N fuse lines based on the fuse enable signals and a comparison result of the corresponding repair addresses and an input address; and a repair control circuit suitable for generating a repair activation signal and an M-bit repair control signal based on signals of the N fuse lines, M being a positive integer smaller than N, and outputting the M-bit repair control signal to multiple address lines by selectively mapping the M-bit repair control signal to some bits of the input address, based on the repair activation signal.

In accordance with another embodiment of the present invention, a semiconductor memory device includes: a plurality of fuse information storages, each corresponding to at least one of a plurality of memory banks and including N latch circuits for storing fuse data transferred from a fuse circuit during a boot-up operation, wherein the N latch circuits drive fuse lines assigned from N fuse lines based on fuse enable signals of the fuse data and a comparison result of repair addresses of the fuse data and an input address; a plurality of repair controllers corresponding to the plurality of the fuse information storages, wherein each of the plurality of the repair controllers generates a repair activation signal and an M-bit repair control signal, M being a positive integer smaller than N, based on signals of the N fuse lines, and outputting the M-bit repair control signal by selectively mapping the M-bit repair control signal to some bits of the input address based on the repair activation signal; an input controller suitable for selectively transferring the input address to one of the plurality of the fuse information storages in response to a row active signal; and an output controller suitable for selecting data outputted from the plurality of the repair controllers and outputting the selected data to multiple address lines in response to the row active signal.

In accordance with yet another embodiment of the present invention, an operating method for a semiconductor memory device includes; providing the semiconductor memory device which is provided with a memory array region including normal memory cells and redundant memory cells which replace repair target memory cells, and a fuse circuit including fuse cells for programming N repair addresses of the repair target memory cells; driving N fuse lines based on N fuse enable signals indicating whether or not the N repair addresses are valid, and a comparison result of the N repair addresses and an input address; generating a repair activation signal and an M-bit repair control signal, M being a positive integer smaller than N, by using signals of the N fuse lines; outputting the M-bit repair control signal to multiple address lines by selectively mapping the M-bit repair control signal to some bits of the input address in response to the repair activation signal; and selectively enabling a redundant path between the repair target memory cells and the redundant memory cells by using the M-bit repair control signal, when the repair activation signal is enabled.

The operating method may further include: storing N fuse data that include the N repair addresses programmed in the fuse cells and the N fuse enable signals, in response to a boot-up signal.

The memory array region may be disposed in a core region, and the fuse circuit may be disposed in a peripheral circuit region.

M may be a least integer among positive integers that are equal to or greater than log₂N.

The driving of the N fuse lines may include: driving the N fuse lines with a ground voltage level, when the N fuse enable signals are disabled or the input address does not coincide with the N repair addresses and when a particular fuse enable signal is enabled and the input address coincides with a repair address corresponding to the particular fuse enable signal, driving a corresponding fuse line with a voltage level higher than the ground voltage level and driving the remaining fuse lines with the ground voltage level.

The outputting the M-bit repair control signal may include: when all the N fuse lines are driven with the ground voltage level and the repair activation signal is disabled, outputting the input address without mapping the M-bit repair control signal to the some bits of the input address; and when a K^{th} fuse line among the N fuse lines is driven with the voltage level higher than the ground voltage level and the repair activation signal is enabled, and outputting the M-bit repair control signal to the multiple address lines by mapping the M-bit repair control signal corresponding to a K^{th} repair address to the some bits of the input address.

### BRIEF DESCRIPTION OF THE DRAWINGS

FIG. 1 is a block diagram illustrating a semiconductor memory device performing a repair operation.

FIG. 2 is a block diagram illustrating a semiconductor memory device in accordance with an embodiment of the present invention.

FIG. 3 is a circuit diagram illustrating a semiconductor memory device in accordance with the embodiment of the present invention.

FIG. 4 is a circuit diagram illustrating a first latch circuit of a fuse latch shown in FIG. 3.

FIG. 5 is a table describing an operation of the semiconductor memory device shown in FIG. 3.

FIG. 6 is a timing diagram illustrating an operation of the semiconductor memory device shown in FIG. 3.

FIG. 7 is a block diagram illustrating a semiconductor memory device in accordance with another embodiment of the present invention.

FIG. 8 is a circuit diagram illustrating an input control circuit shown in FIG. 7.

FIG. 9 is a timing diagram illustrating an operation of the semiconductor memory device shown in FIG. 7.

### DETAILED DESCRIPTION

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

Hereafter, a repair operation of a semiconductor memory device is described with reference to the accompanying drawing.

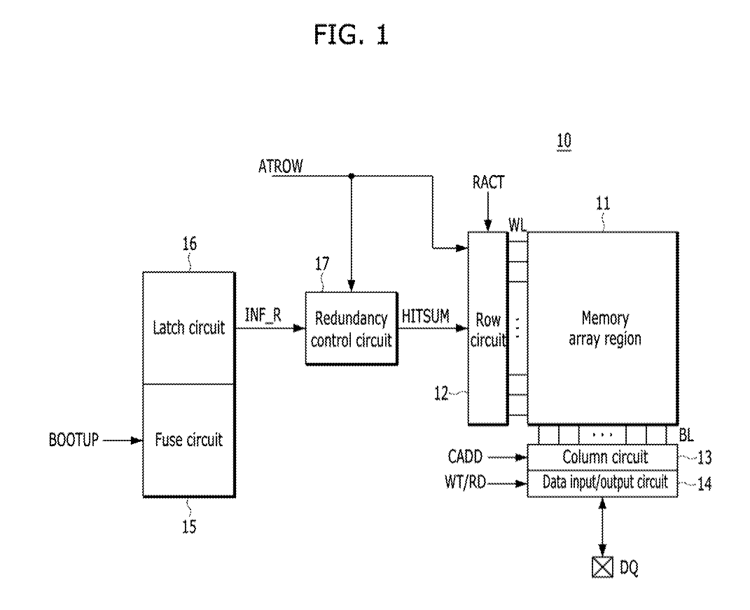

FIG. 1 is a block diagram illustrating a semiconductor memory device 10. For the sake of convenience in description, FIG. 1 shows the minimal structures for performing a repair operation, and it is presumed that the semiconductor memory device 10 includes one memory bank.

Referring to FIG. 1, the semiconductor memory device 10 may include a memory array region 11, a row circuit 12, a column circuit 13, a data input/output circuit 14, a fuse circuit 15, a latch circuit 16, and a redundancy control circuit 17.

The fuse circuit 15 may include a plurality of fuse cells (not shown) for programming an address corresponding to a repair target word line (hereafter, referred to as a repair address). The fuse circuit 15 may output the repair address that is programmed in response to a boot-up signal BOOTUP to the latch circuit 16. The latch circuit 16 may store the repair address that is received from the fuse circuit 15 as repair information INF_R and output the repair information INF_R to the redundancy control circuit 17.

The redundancy control circuit 17 may compare the repair information INF_R received from the latch circuit 16 with a row address ATROW that is inputted from the outside of the semiconductor memory device, and output a repair control signal HITSUM. If the repair information INF_R is the same as the row address ATROW, the redundancy control circuit 17 enables the repair control signal HITSUM and outputs the enabled repair control signal HITSUM.

The memory array region 11 may include a nor mal cell region (not shown) and a redundancy cell region (not shown). If a defective memory cell which is a repair target memory cell is detected in the normal cell region, a normal word line where the repair target memory cell is positioned which is a repair target word line may be replaced with a redundant word line of the redundancy cell region.

The row circuit 12 may enable a word line that is selected based on the row address ATROW in response to a row active command RACT. When the repair control signal HITSUM is enabled, the row circuit 12 may enable a redundant word line instead of the word line that is designated by the row address ATROW. In this way, the repair target word line corresponding to the repair information INF_R that is stored in the latch circuit 16 may be replaced with the redundant word line.

The column circuit 13 may access a data of a bit line BL that is selected based on a column address CADD.

The data input/output circuit 14 may output a data transferred from the bit line BL that is selected based on the column address CADD to a DQ pad in response to a read signal RD during a read operation. During a write operation, the data input/output circuit 14 may transfer a data that is inputted through the DQ pad to a bit line BL corresponding to the column address CADD in response to a write signal WT and store the data.

Furthermore, in the semiconductor memory device 10, the fuse circuit 15 may program the repair information INF_R corresponding to a repair address in its fuse cells, and output the repair information INF_R to the latch circuit 16 in response to the boot-up signal BOOTUP. Herein, the repair information INF_R stored in the fuse circuit 15 is not directly used but the repair information INF_R is moved into and stored in the latch circuit 16 and then used. The reason is as follows.

Since the fuse circuit 15 is formed in an array type, it takes a predetermined time to call out the data stored therein. Since it is impossible to instantly read out the data, it is impossible to perform a repair operation by directly using the data stored in the fuse circuit 15. Therefore, the boot-up operation where the repair information INF_R stored in the fuse circuit 15 is transferred to and stored in the latch circuit 16 is performed, and then after the boot-up operation, the repair operation may be performed using the data stored in the latch circuit 16.

As the capacity of a semiconductor memory device is increased, the number of the fuse cells in the fuse circuit 15 and the unit latches of the latch circuit 16 that store the repair information of a row address or a column address are increasing together. However, since the fuse circuit 15 and the latch circuit 16 are disposed in the core region which has a relatively smaller available area than the peripheral circuit region, the density of the core region, which is already high, is escalated.

Hereafter, a semiconductor memory device 100 in which a fuse circuit and a latch circuit are disposed in a peripheral circuit region and repair information is transferred through an existing address line is described in accordance with an embodiment of the present invention.

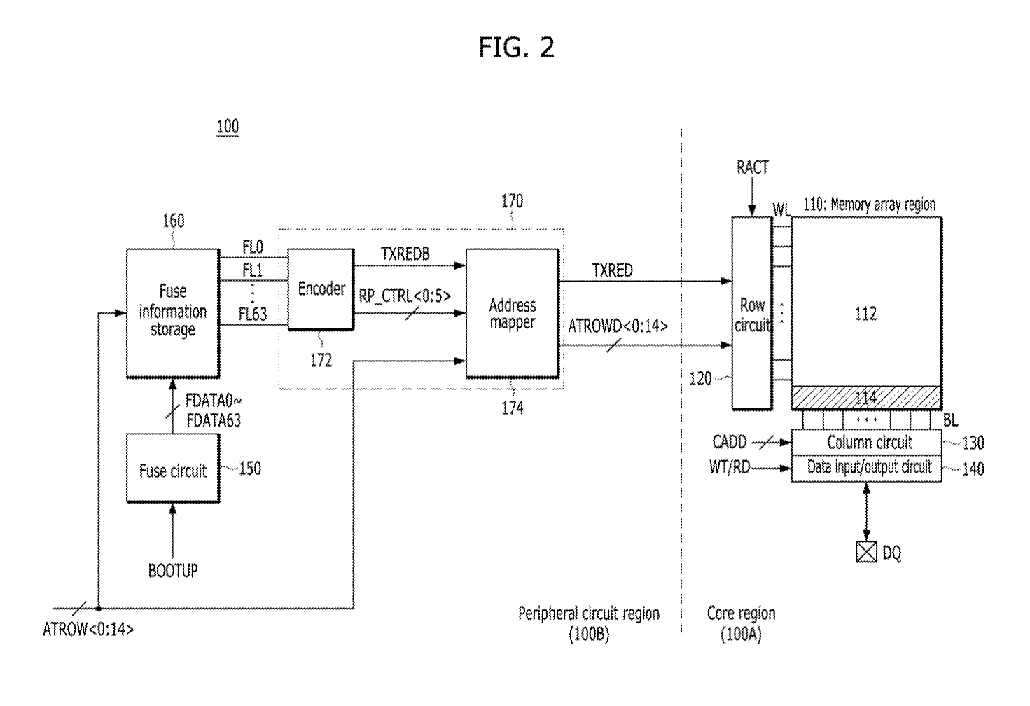

FIG. 2 is a block diagram illustrating a semiconductor memory device 100 in accordance with an embodiment of the present invention.

Referring to FIG. 2, the semiconductor memory device 100 may include a memory array region 110, a row circuit 120, a column circuit 130, a data input/output circuit 140, a fuse circuit 150, a fuse information storage 160, and a repair control circuit 170.

Although not illustrated in the drawing, the semiconductor memory device 100 may include a command decoder and an active signal generator. The command decoder may generate a refresh signal REF (not shown), a write signal WT, a read signal RD, an active signal ACT (not shown), and a precharge signal PCG (not shown) by decoding external commands RST, /CS, /RAS, /CAS, and /WE (not shown) that are inputted from the outside of the semiconductor memory device 100. The active signal generator may generate a row active signal RACT in response to the active signal ACT and the precharge signal PCG. Also, the semiconductor memory device 100 may further include an address buffer (not shown) for buffering an external input address and outputting a row address and a column address CADD, and a refresh controller (not shown) for selecting one between the row address and a refresh address that is generated by counting the refresh signal REF and outputting a target row address ATROW.

The memory array region 110 may include a plurality of cell matrices that include memory cells for storing data. The memory cells may be coupled to the row circuit 120 through word lines WL, and coupled to the column circuit 130 through bit lines BL. Data may be stored in selected memory cells that are selected based on a word line enabling signal outputted from the row circuit 120 and a column selection signal outputted from the column circuit 130. According to the embodiment of the present invention, the memory array region 110 may be formed of volatile memory cells. According to another embodiment of the present invention, the memory array region 110 may be formed of Dynamic Random Access Memory (DRAM) memory cells.

The memory array region 110 may include a normal cell region 112 where normal memory cells are disposed and a redundancy cell region 114 where redundant memory cells are disposed. When a defective memory cell, which may be also called a repair target memory cell is detected in the normal cell region 112, the normal word line where the defective memory cell is positioned, which is a repair target word line, may be replaced with a redundant word line of the redundancy cell region 114.

Hereafter, for the sake of convenience in description, it is presumed that the memory array region 110 includes one memory bank, and the target row address ATROW<0:14> is formed of 15 bits, and the redundancy cell region 114 includes 64 redundant word lines, and a row repair operation is performed in this environment. Also, it is presumed that a repair address corresponding to each of the 64 redundant word lines is formed of 12 bits.

The fuse circuit 150 may include fuse cells (not shown) for programming the repair addresses of repair target memory cells, and output fuse data that include the repair addresses that are programmed in the fuse cells and a fuse enable signal. Herein, when there are 64 redundant word lines, there are 64 repair addresses for respectively designating the 64 redundant word lines. Therefore, the fuse circuit 150 may output first to 64^{th} fuse data FDATA0 to FDATA63 that respectively correspond to the repair addresses programmed in the fuse cells in response to a boot-up signal BOOTUP. Herein each of the first to 64^{th} fuse data FDATA0 to FDATA63 may be formed of 13 bits, one bit of which is a fuse enable signal, for informing whether a programmed repair address is valid or not and 12 bits of which are a repair address.

The fuse information storage 160 may include 64 latch circuits (not shown) that respectively store the first to 64^{th} fuse data FDATA0 to FDATA63 which are received from the fuse circuit 150. The 64 latch circuits may be coupled to 64 fuse lines FL0 to FL63, which are first to 64^{th} fuse lines FL0 to FL63, respectively, in 1:1, and an assigned fuse line may be driven based on the fuse enable signal of a corresponding fuse data FDATA0 to FDATA63 and a comparison result of a repair address and the target row address ATROW<0:14> inputted from the outside.

The repair control circuit 170 may generate a repair activation signal TXREDB and a 6-bit repair control signal RP_CTRL<0:5> by encoding the signal of the first to 64^{th} fuse lines FL0 to FL63, and may map the 6-bit repair control signal RP_CTRL<0:5> to some bits of the target row address ATROW<0:14>, for example, ATROW<0:5> response to the repair activation signal TXREDB and output a final target row address ATROWD<0:14>. The repair control circuit 170 may invert the repair activation signal TXREDB and output a post-repair activation signal TXRED. However, this is just an example, and the repair activation signal TXREDB or the post-repair activation signal TXRED may be used as a signal for deciding whether or not to form a redundant path between the repair target word line of the normal cell region 112 and a redundant word line of the redundancy cell region 114.

In this embodiment of the present invention, the memory array region 110, the row circuit 120, and the column circuit 130 are disposed in the core region 100A, and the fuse circuit 150, the fuse information storage 160, and the repair control circuit 170 may be disposed in the peripheral circuit region 100B.

To be specific, the repair control circuit 170 may include an encoder 172 and an address mapper 174.

The encoder 172 may encode the signals of the first to 64^{th} fuse lines FL0 to FL63 and generate the repair activation signal TXREDB and the 6-bit repair control signal RP_CTRL<0:5>. The address mapper 174 may map the 6-bit repair control signal RP_CTRL<0:5> to some bits of the target row address ATROW<0:14>, for example, ATROW<0:5>, in response to the repair activation signal TXREDB and output the final target row address ATROWD<0:14>. Additionally, the address mapper 174 may invert the repair activation signal TXREDB and output the post-repair activation signal TXRED.

In some embodiments, the number M of the bits of the repair control signal RP_CTRL<0:5> may be smaller than the number N of the fuse lines FL0 to FL63 (that is M<N). According to an embodiment of the present invention, the number Ni of the bits of the repair control signal RP_CTRL<0:5> may be an integer that is the least among the positive integers which are equal to or greater than log₂N. For example, when the number N of the fuse lines FL0 to FL63 is 64 (that is, N=64), the number M of the bits of the repair control signal RP_CTRL<0:5> may be 6 (that is, M=6). Herein, the repair activation signal TXREDB is a signal for deciding whether or not to form a redundant path between the repair target word line of the normal cell region 112 and a redundant word line of the redundancy cell region 114, and the 6-bit repair control signal RP_CTRL<0:5> is a signal for indicating the position of the redundant word line to be replaced with the repair target word line. For example, when the repair activation signal TXREDB is enabled to a logic low level and the 6-bit repair control signal RP_CTRL<0:5> is ‘100000’, a redundant path may be formed between the repair target word line of the normal cell region 112 and the second redundant word line among the 64 redundant word lines of the redundancy cell region 114.

The row circuit 120 may generate a word line enabling signal for enabling a word line WL that corresponds to the final target row address ATROWD<0:14> in response to the row active signal RACT. When the post-repair activation signal TXRED is enabled, the row circuit 120 may decode the final target row address ATROWD<0:14> and enable a redundant word line that is designated by some bits of the final target row address ATROWD<0:14>, for example, ATROWD<0:5>, instead of a normal word line designated by the final target row address ATROWD<0:14>. In this way, the repair target word line corresponding to the repair address which is programmed in the fuse circuit 150 may be replaced with the redundant word line.

The column circuit 130 may decode the column address CADD and generate a column selection signal for selecting a particular bit line BL.

The data input/output circuit 140 may output the data that is transferred from the bit line BL which is selected based on the column address CADD in response to the read signal RD, and transfer the data inputted through the DQ pad to a bit line BL corresponding to the column address CADD in response to the write signal WT and store the data.

According to the embodiment of the present invention, the memory array region 110, the row circuit 120, and the column circuit 130 are disposed in the core region 100A, and the fuse circuit 150, the fuse information storage 160, and the repair control circuit 170 are disposed in the peripheral circuit region 100B. Furthermore, the repair control signal RP_CTRL<0:5> outputted from the encoder 172 of the repair control circuit 170 is mapped to some bits of the target row address ATROW<0:14>, for example, ATROW<0:5> and transferred to the row circuit 120. That is, the fuse circuit 150 and the fuse information storage 160 that occupy wide area may be disposed in the peripheral circuit region 100B, and repair information may be transferred from the peripheral circuit region 100B to the core region 100A through an existing address line. Although a transfer line for transferring the post-repair activation signal TXRED may be added in addition to the existing address lines, in this embodiment of the present invention, the high density of the core region 100A is relieved and the efficiency of using the area may be increased by distributively disposing the constituent elements in the peripheral circuit region 100B instead of the core region 100A which has a relatively smaller available area than the peripheral circuit region 100A.

Additionally, whereas a conventional semiconductor memory device has a decreased timing margin due to long routing of the target address ATROW since the latch circuits are disposed in the core region and the latch circuits are serially arranged on one side of the core region in support of an any-to-any redundancy scheme, the semiconductor memory device 100 in accordance with an embodiment of the present invention may be secured with timing margin since a fuse latch unit is disposed in the peripheral circuit region 100B.

Hereafter, the embodiment, of the present invention may be described in detail with reference to the accompanying drawings.

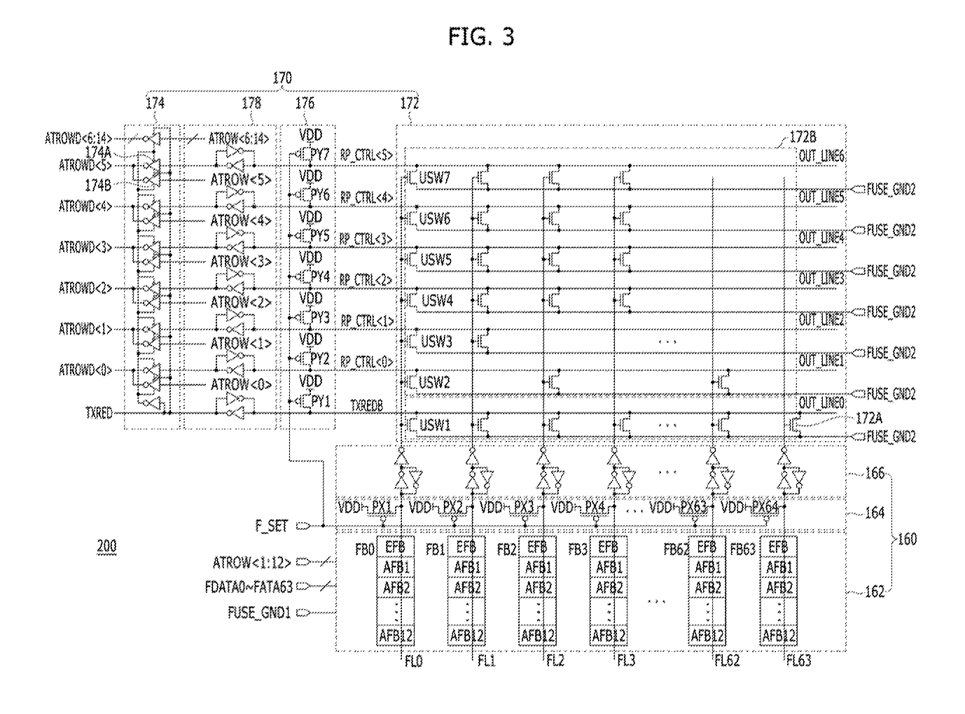

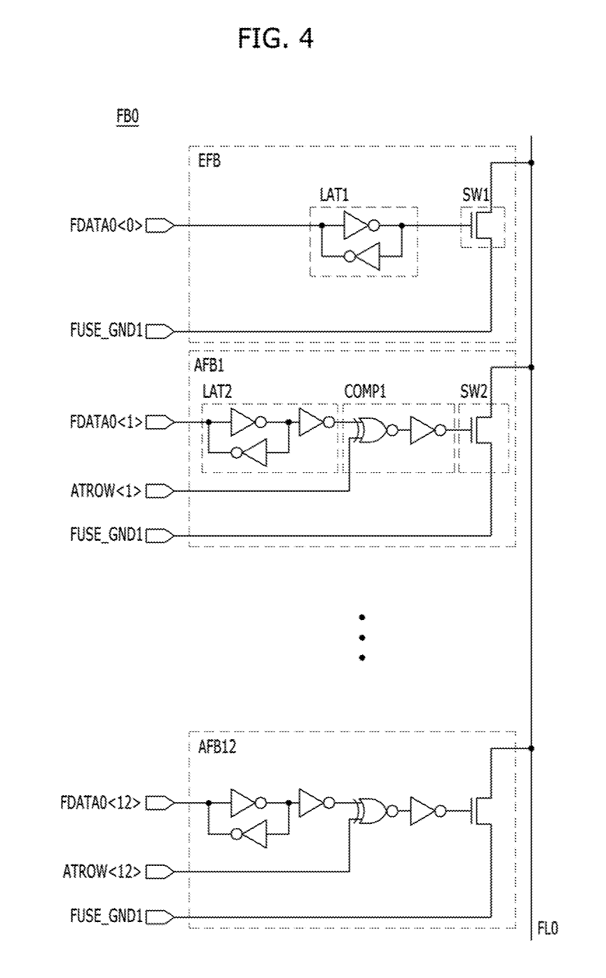

FIG. 3 is a circuit diagram illustrating a semiconductor memory device 200 in accordance with an embodiment of the present invention. FIG. 4 is a circuit diagram illustrating a first latch circuit FB0 of a fuse latch unit 162 shown in FIG. 3. FIG. 3 illustrates the fuse information storage 160 and the repair control circuit 170 that are disposed in the peripheral circuit region 100B among the constituent elements shown in FIG. 2. The same constituent elements appearing in FIGS. 2 to 4 are given with the same reference numerals.

Referring to FIG. 3, the semiconductor memory device 200 may include the fuse information storage 160 and the repair control circuit 170 in the peripheral circuit region 100B.

The fuse information storage 160 may include the fuse latch 162, the first precharger 164, and the first output latch 166.

The fuse latch 162 may include first to 64^{th} latch circuits FB0 to FB63 for respectively storing first to 64^{th} fuse data FDATA0 to FDATA63 that correspond to first to 64^{th} fuse lines FL0 to FL63 in 1:1 and are outputted from the fuse circuit 150 (see FIG. 2). Each of the first to 64^{th} latch circuits FB0 to FB63 may compare a repair address of the stored first to 64^{th} fuse data FDATA0 to FDATA63 with an external target row address ATROW<1:12> which is inputted from the outside of the semiconductor memory device 200, and drive a fuse line that is assigned based on a comparison result. Herein, the external target row address ATROW<0:14> may be formed of 15 bits, but a case in which 12 bits of the target row address ATROW<1:12> are used as a row address is taken as an example and described herein.

The first precharger 164 may precharge the first to 64^{th} fuse lines FL0 to FL63 with a voltage level that is higher than a ground voltage level for example, a power source voltage VDD level, in response to an initialization signal F_SET. According to another embodiment of the present invention, the first precharger 164 may include 64 transistors PX1 to PX64 that are coupled to a power source voltage VDD terminal and the first to 64^{th} latch circuits FB0 to FB63 and turned on in response to the initialization signal F_SET.

The first output latch 166 may latch the signals of the first to 64^{th} fuse lines FL0 to FL63. In this embodiment of the present invention, the first output latch 166 may include 64 unit output latches that respectively correspond to the first to 64^{th} fuse lines FL0 to FL63, and each unit output latch may be formed of an inverter latch and an inverter.

The repair control circuit 170 may include an encoder 172 and an address mapper 174.

The encoder 172 may generate a repair activation signal TXREDB and a 6-bit repair control signal RP_CTRL<0:5> by encoding the signals of the first to 64^{th} fuse lines FL0 to FL63 and output them through first to seventh output lines OUT_LINE0 to OUT_LINE6.

Specifically, the encoder 172 may include a first encoding unit 172A for generating the repair activation signal TXREDB and a second encoding unit 172B for generating the 6-bit repair control signal RP_CTRL<0:5>.

The first encoding unit 172A may be coupled in parallel between the first output line OUT_LINE0 and a second ground line FUSE_GND2. The first encoding unit 172A may include 64 first unit switches USW1 that are respectively turned on in response to the signals of the first to 64^{th} fuse lines FL0 to FL63. The second encoding unit 172B may include 32 second to seventh unit switches USW2 to USW7 that are coupled in parallel between one output line among the second to seventh output lines OUT_LINE1 to OUT_LINE6 and the second ground line FUSE_GND2. In some embodiments, the number of each of the second to seventh unit switches USW2 to USW7 may be smaller than the number of the first unit switches USW1. According to an embodiment of the present invention, the number of each of the second to seventh unit switches USW2 to USW7 may be the least integer among positive integers that are equal to or greater than (the number of the first unit switches USW1)/2. For example, when the number of the first unit switches USW1 is 64, the number of each of the second to seventh unit switches USW2 to USW7 may be 32.

The address mapper 174 may map the 6-bit repair control signal RP_CTRL<0:5> to some bits of the target, row address ATROW<0:14>, for example, ATROW<0:5>, in response to the repair activation signal TXREDB, and output the final target row address ATROWD<0:14>. When the repair activation signal TXREDB is enabled to a logic low level, the address mapper 174 may map the 6-bit repair control signal RP_CTRL<0:5> transferred through the second to seventh output lines OUT_LINE1 to OUT_LINE6 to some bits of the target row address ATROW<0:14>, for example, ATROW<0:5>, and output the final target row address ATROWD<0:14>. Furthermore, when the repair activation signal TXREDB is disabled to a logic high level the address mapper 174 may output the target row address ATROW<0:14> as the final target row address ATROWD<0:14>.

Specifically, the address mapper 174 may include a first driving unit 174A and a second driving unit 174B.

When the repair activation signal TXREDB is enabled to a logic low level, the first driving unit 174A may transfer the 6-bit repair control signal RP_CTRL<0:5> that is received through the second to seventh output lines OUT_LINE1 to OUT_LINE6 through some of the address lines. When the repair activation signal TXREDB is disabled to a logic high level, the second driving unit 174B may transfer the final target row address ATROWD<0:14> through an address line. In this embodiment of the present invention, each of the first driving unit 174A and the second driving unit 174B may be formed as an inverter.

Additionally, the repair control circuit 170 may further include a second precharger 176 and a second output latch 178.

The second precharger 176 may precharge the first to seventh output lines OUT_LINE0 to OUT_LINE6 with a predetermined level for example, a power source voltage VDD level in response to the initialization signal F_SET. According to the embodiment of the present invention, the second precharger 176 may include 7 transistors PY1 to PY7 that are coupled to a power source voltage VDD terminal and the first to seventh output lines OUT_LINE0 to OUT_LINE6 and are turned on in response to the initialization signal F_SET.

The second output latch 178 may invert the signals of the first to seventh output lines OUT_LINE0 to OUT_LINE6 and latch the inverted signals. In this embodiment of the present invention, the second output latch 178 may include 7 unit output latches that respectively correspond to the first to seventh output lines OUT_LINE0 to OUT_LINE6, and each unit output latch may be formed of an inverter latch.

Moreover, each of the first to 64^{th} latch circuits FB0 to FB63 of the fuse latch unit 162 may include a fuse enable latch EFB and a plurality of address latches AFB1 to AFB12. Herein, each of the first to 64^{th} fuse data FDATA0 to FDATA63 may include 13 bits, one bit of which is a one-bit fuse enable signal that informs whether or not a programmed repair address is valid and 12 bits of which are the repair address. The fuse enable latch EFB may store the one-bit fuse enable signal, and the address latches AFB1 to AFB12 may store the 12-bit repair address.

FIG. 4 illustrates a circuit diagram of the first latch circuit FB0 among the first to 64^{th} latch circuits FB0 to FB63. Since the structures of the second to 64^{th} latch circuits FB1 to FB63 are substantially the same as that of the first latch circuit FB0, the first latch circuit FB0 is representatively described as an example, herein.

The first latch circuit FB0 may include the fuse enable latch EFB and the first to 12^{th} address latches AFB1 to AFB12. The fuse enable latch EFB receives one bit FDATA0<0> among the 13-bit first fuse data FDATA0 as the fuse enable signal and drives the first fuse line FL0. The first to 12^{th} address latches AFB1 to AFB12 receive the second to 13^{th} bits FDATA0<1:12> as the repair address and drive the first fuse line FL0.

When the one bit FDATA0<0> is disabled, that is, when the fuse enable signal is disabled, the fuse enable latch EFB may drive the first fuse line FL0 with a ground voltage level. The fuse enable latch EFB may include a first latch LAT1 and a first switch SW1. The first latch LAT1 stores the first bit FDATA0<0> of the first fuse data FDATA0 transferred from a fuse circuit 150 during a boot-up operation. The first switch SW1 is coupled between the first fuse line FL0 and the first ground line FUSE_GND1 and is, turned on according to an output signal of the first latch LAT1. According to an embodiment of the present invention, the first latch LAT1 may be formed as an inverter latch, and the first switch SW1 may be an NMOS transistor.

The first to 12^{th} address latches AFB1 to AFB12 may compare the corresponding bit of the second to 13^{th} bits FDATA0<1:12> with the corresponding bit of the target row address ATROW<1:12>, respectively. If there is any one bit that is different, the first to 12^{th} address latches AFB1 to AFB12 may drive the first fuse line FL0 with the ground voltage level.

Since the first to 12^{th} address latches AFB1 to AFB12 have the same structure, the first address latch AFB1 is representatively described, herein, as an example. The first address latches AFB1 may include a second latch LAT2, a comparator COMP1 and a second switch SW2. The second latch LAT2 stores the second bit. FDATA0<1> of the first fuse data FDATA0 transferred from the fuse circuit 150 during the boot-up operation. The comparator COMP1 compares an output signal of the second latch LAT2 with the corresponding bit ATROW<1> of the target row address ATROW<1:12>. The second switch SW2 is coupled between the first fuse line FL0 and the first ground line FUSE_GND1 and is turned on according to an output signal of the comparator COMP1. According to an embodiment of the present invention, the second latch LAT2 may be formed of an inverter latch and an inverter, the comparator COMP1 may be formed of an exclusive NOR (XNOR) gate for performing an exclusive NOR operation and an inverter, and the second switch SW2 may be an NMOS transistor.

Therefore, the first latch circuit FB0 may drive the first fuse line FL0 with the ground voltage level, when the fuse enable signal of the first fuse data FDATA0 is disabled or the repair address of the first fuse data FDATA0 does not coincide with the target row address ATROW<1:12>. Additionally, the first latch circuit FB0 may maintain the first fuse line FL0 in the previous state, for example, a precharge state, when the fuse enable signal of the first fuse data FDATA0 is enabled and at the same time the repair address of the first fuse data FDATA0 coincides with the target row address ATROW<1:12>.

Herein, the second ground line FUSE_GND2 used in the repair control circuit 170 and the first ground line FUSE_GND1 used in the fuse information storage 160 may receive a ground voltage at different timings. That is, a semiconductor memory device may be guaranteed with operation stability by supplying the ground voltage to the first ground line FUSE_GND1 first and then supplying the ground voltage to the second ground line FUSE_GND2 so that an encoding operation may be performed after a fuse data is stably latched.

Hereafter, an operation of the semiconductor memory device 200 in accordance with an embodiment of the present invention is described with reference to FIGS. 3 to 6.

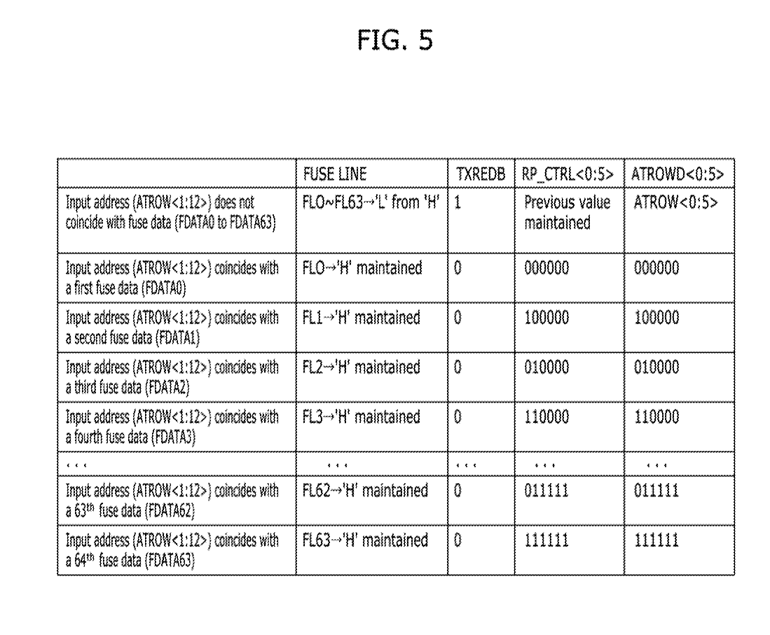

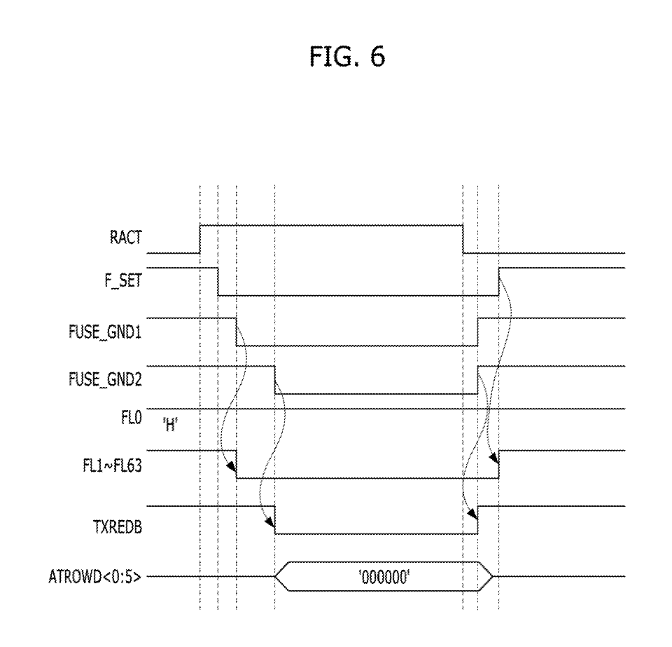

FIG. 5 is a table describing an operation of the semiconductor memory device 200 shown in FIG. 3. FIG. 6 is a timing diagram illustrating an operation of the semiconductor memory device 200 shown in FIG. 3.

Referring to FIG. 5, an operation of generating the repair activation signal TXREDB and the 6-bit repair control signal RP_CTRL<0:5> based on the signals of the first to 64^{th} fuse lines FL0 to FL63 is described.

First, when the fuse enable signals of the first to 64^{th} fuse data FDATA0 to FDATA63 are disabled or the repair addresses of the first to 64^{th} fuse data FDATA0 to FDATA63 do not coincide with the target row address ATROW<1:12>, the fuse information storage 160 may drive all the first to 64^{th} fuse lines FL0 to FL63 with the ground voltage level. As a result, the repair control circuit 170 may disable the repair activation signal TXREDB to a logic high level, output the target row address ATROW<0:14> as the final target row address ATROWD<0:14>, and invert the repair activation signal TXREDB and output the inverted repair activation signal TXREDB as the post-repair activation signal TXRED.

Subsequently, when the fuse enable signal of the K^{th} fuse data FDATAK among the first to 64^{th} fuse data FDATA0 to FDATA63 is enabled and, at the same time, the repair address of the K^{th} fuse data FDATAK coincides with the target row address ATROW<1:12>, the fuse information storage 160 may maintain the K^{th} fuse line at the precharge state, for example, at the power source voltage VDD level which is higher than the ground voltage level and the other fuse lines may be driven with the ground voltage level. Accordingly the repair control circuit 170 may enable the repair activation signal TXREDB to a logic low level, map the repair control signal RP_CTRL<0:5> to some bits of the target row address ATROW<0:14>, for example, ATROW<0:5>, and output the final target row address ATROWD<0:14>. Furthermore, the repair control circuit 170 may invert the repair activation signal TXREDB and output the inverted repair activation signal TXREDB as the post-repair activation signal TXRED.

FIG. 6 illustrates a case in which the fuse enable signal of the first fuse data FDATA0 among the first to 64^{th} fuse data FDATA0 to FDATA63 is enabled and, at the same time, the repair address of the first fuse data FDATA0 coincides with the target row address ATROW<1:12>.

First, when the row active signal RACT is enabled, the initialization signal F_SET may be enabled to a logic low level, and the first precharger 164 may precharge the first to 64^{th} fuse lines FL0 to FL63 with the power source voltage VDD level.

When the fuse enable signal of the first fuse data FDATA0 among the first to 64^{th} fuse data FDATA0 to FDATA63 is enabled and, at the same time, the repair address of the first fuse data FDATA0 coincides with the target row address ATROW<1:12>, all the internal switches SW1 and SW2 of the first latch circuit FB0 of the fuse information storage 160 may be turned off and thereby the first fuse line FL0 may be maintained at the precharge state, that is, the power source voltage VDD level. Furthermore, the remaining second to 64^{th} latch circuits FB1 to FB63 may have at least one switch to be turned on and thereby the corresponding fuse lines FL1 to FL63 may be driven with the ground voltage level.

In this way, the repair control circuit 170 may enable the repair activation signal TXREDB to a logic low level and generate a repair control signal RP_CTRL<0:5> having ‘000000’. In response to the repair activation signal TXREDB, the repair control circuit 170 may map the repair control signal RP_CTRL<0:5> having ‘000000’ that is transferred through the second to seventh output lines OUT_LINE0 to OUT_LINE6 to some bits of the target row address ATROW<0:14>, for example, ATROW<0:5>, and output the final target row address ATROWD<0:14>. Additionally, the repair control circuit 170 may invert the repair activation signal TXREDB and output the post-repair activation signal TXRED.

Herein, the fuse data may be stably latched by driving the first ground line FUSE_GND1 with a logic low level and then driving the second ground line FUSE_GND2 with a logic low level, and thereby the encoding operation may be performed after the fuse line is driven stably.

Although a case in which the memory array region includes one memory bank in the embodiment of the present invention, the technology of the present invention may be applied to a case in which a memory array region includes a plurality of memory banks.

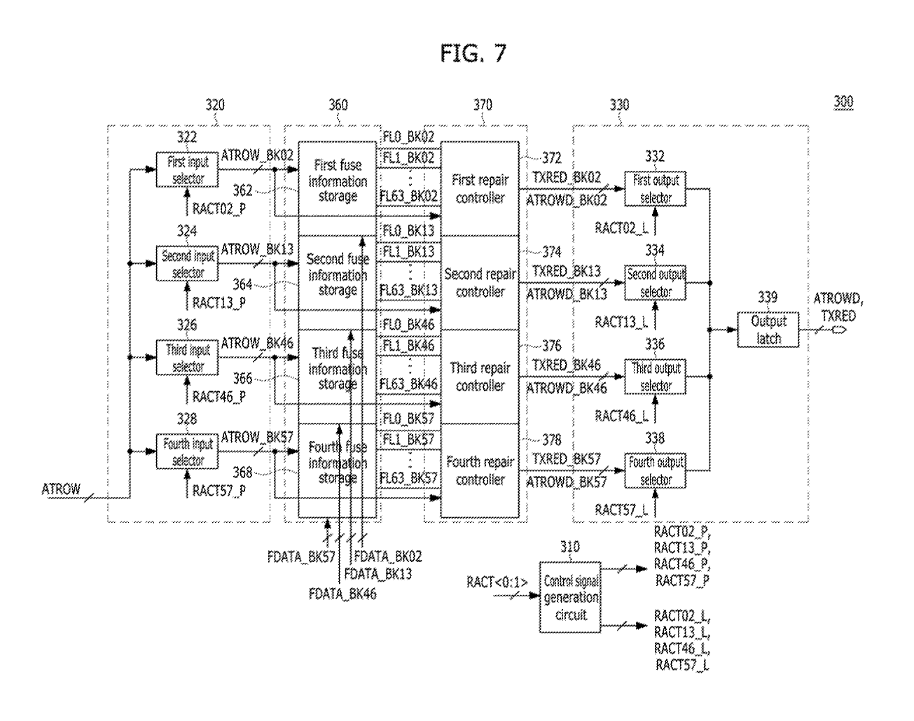

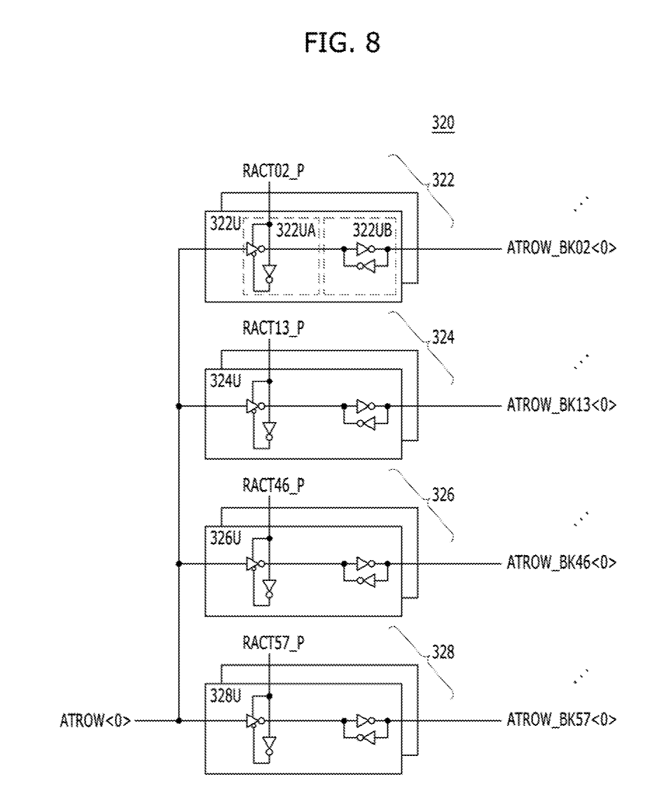

FIG. 7 is a block diagram illustrating a semiconductor memory device 300 in accordance with another embodiment of the present invention. FIG. 8 is a circuit diagram illustrating an input control circuit 320 shown in FIG. 7. Hereafter, a case in which a memory array region includes first to eighth memory banks BANK0 to BANK7 (not shown) and the first memory bank BANK0 and the third memory bank BANK2, the second memory bank BANK1 and the fourth memory bank BANK3, the fifth memory bank BANK4 and the seventh memory bank BANK6, and the sixth memory bank BANK5 and the eighth memory bank BANK7 share first to fourth fuse circuits (not shown), respectively, is described.

FIG. 7 illustrates a fuse information storage 360 and a repair control circuit 370 that are disposed in a peripheral circuit region of the semiconductor memory device 300. Herein, the structure of a core region of FIG. 7 may be substantially the same as the structure of the core region shown in FIG. 2. In the embodiment of the present invention shown in FIG. 7, it is presumed that there are first to eighth memory banks BANK0 to BANK7 (not shown), and the first memory bank BANK0 and the third memory bank BANK2, the second memory bank BANK1 and the fourth memory bank BANK3, the fifth memory bank BANK4 and the seventh memory bank BANK6, and the sixth memory bank BANK5 and the eighth memory bank BANK7 share first to fourth fuse circuits (not shown) respectively, and a 2-bit row active signal RACT<0:1> may be inputted to select a word line of each memory bank.

The semiconductor memory device 300 may include an input control circuit 320, an output control circuit 330, the fuse information storage 360, and the repair control circuit 370. The semiconductor memory device 300 may further include a control signal generation circuit 310. When the row active signal RACT<0:1> is enabled, the control signal generation circuit 310 generates first to fourth row active pulse signals RACT02_P, RACT13_P, RACT46_P and RACT57_P which pulse in a predetermined period, and generates first to fourth row active level signals RACT02_L, RACT13_L, RACT46_L and RACT57_L which maintain their level in a predetermined period.

The fuse information storage 360 and the repair control circuit 370 may include a first fuse information storage 362 and a first repair controller 372 that correspond to the first memory bank BANK0 and the third memory bank BANK2, respectively; a second fuse information storage 364 and a second repair controller 374 that correspond to the second memory bank BANK1 and the fourth memory bank BANK3, respectively; a third fuse information storage 366 and a third repair controller 376 that correspond to the fifth memory bank BANK4 and the seventh memory bank BANK6, respectively; and a fourth fuse information storage 368 and a fourth repair controller 378 that correspond to the sixth memory bank BANK5 and the eighth memory bank BANK7, respectively. The first to fourth fuse information storages 362 to 368 may receive first to fourth fuse data FDATA_BK02, FDATA_BK13, FDATA_BK46 and FDATA_BK57 that are programmed in first to fourth fuse circuits respectively, during a boot-up operation. Since the structures of the first to fourth fuse information storages 362 to 368 are substantially the same as the structure of the fuse information storage 160 shown in FIG. 2, and the structures of the first to fourth repair controllers 372 to 378 are substantially the same as the structure of the repair control circuit 170 shown in FIG. 2, a detailed description of those structures are omitted below.

The input control circuit 320 may selectively transfer an external target row address ATROW inputted from the outside of the semiconductor memory device 300 to one among the first to fourth fuse information storages 362 to 368 In response to the first to fourth row active pulse signals RACT02_P, RACT13_P, RACT46_P and RACT57_P.

Specifically, the input control circuit 320 may include first to fourth input selectors 322 to 328. The first input selector 322 may transfer the target row address ATROW as a first bank target row address ATROW_BK02 to the first fuse information storage 362 in response to the first row active pulse signal RACT02_P. The second input selector 324 may transfer the target row address ATROW as a second bank target row address ATROW_BK13 to the second fuse information storage 364 in response to the second row active pulse signal RACT13_P. The third input selector 326 may transfer the target row address ATROW as a third bank target row address ATROW_BK46 to the third fuse information storage 366 in response to the third row active pulse signal RACT46_P. The fourth input selector 328 may transfer the target row address ATROW as a fourth bank target row address ATROW_BK57 to the fourth fuse information storage 368 in response to the fourth row active pulse signal RACT57_P.

Referring to FIG. 8, the first to fourth input selectors 322 to 328 may be provided with unit selectors 322U, 324U, 326U and 328U that correspond to the bits of the target row address ATROW, respectively. For example, the unit selector 322U may include a transfer unit 322UA and an input latch unit 322UB. When the first row active pulse signal RACT02_P is enabled, the transfer unit 322UA may transfer a first bit ATROW<0> of the target row address ATROW. The input latch unit 322UB may latch an output of the transfer unit 322UA and output it as a first bit ATROW_BK02<0> of the first bank target row address ATROW_BK02. In this embodiment of the present invention, the transfer unit 322UA may be formed as an inverter, and the input latch unit 322UB may be formed as an inverter latch.

Referring to FIG. 7 again, the output control circuit 330 may select one among the data that are transferred from the first to fourth repair controllers 372 to 378 and output the selected data as a final post-repair activation signal TXRED and a final target row address ATROWD in response to the first to fourth active level signals RACT02_L, RACT13_L, RACT46_L and RACT57_L.

Specifically, the output control circuit 330 may include first to fourth output selectors 332 to 338 and an output latch 339.

The first output selector 332 may selectively output the data transferred from the first repair controller 372, which is a first bank repair activation signal TXRED_BK02, and the first bank target row address ATROW_BK02 in response to the first row active level signal RACT02_L. The second output selector 334 may selectively output the data transferred from the second repair controller 374, which is a second bank repair activation signal TXRED_BK13, and a second bank target row address ATROW_BK13 in response to the second row active level signal RACT13L. The third output selector 336 may selectively output the data transferred from the third repair controller 376, which is a third bank repair activation signal TXRED_BK46, and a third bank target row address ATROW_BK46 in response to the third row active level signal RACT46_L. The fourth output selector 338 may selectively output the data transferred from the fourth repair controller 378, which is a fourth bank repair activation signal TXRED_BK57, and a fourth bank target row address ATROW_BK57 in response to the fourth row active level signal RACT57_L. In this embodiment of the present invention, the first to fourth output selectors 332 to 338 may be formed as transfer gates.

Hereafter, an operation of the semiconductor memory device 300 is described with reference to FIGS. 7 to 9.

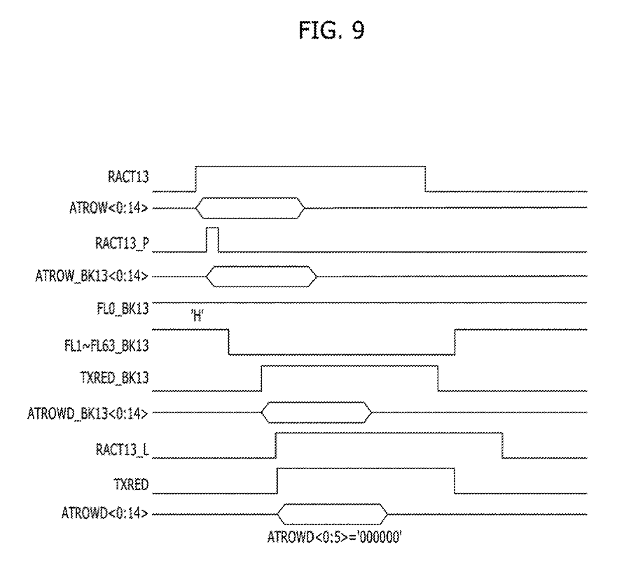

FIG. 9 is a timing diagram illustrating an operation of the semiconductor memory device 300 shown in FIG. 7. It is presumed in the embodiment of the present invention shown in FIG. 9 that the target row address ATROW<0:14> is formed of 15 bits and there are 64 redundant word lines. Also, it is presumed that a row active signal RACT13 among the row active signals RACT<0:1> is enabled to select the word lines of the second memory bank BANK1 and the fourth memory bank BANK3.

Referring to FIG. 9, the row active signal RACT13 is enabled, and the target row address ATROW<0:14> is inputted from the outside of the semiconductor memory device 300.

When the row active signal RACT13 is enabled, the control signal generation circuit 310 may generate a second row active pulse signal RACT13_P that pulses in a predetermined period, and may generate a second row active level signal RACT13_L that maintains its level in a predetermined period.

The second input selector 324 may transfer the target row address ATROW<0:14> as a second bank target row address ATROW_BK13<0:14> to the second fuse information storage 364 in response to the second row active pulse signal RACT13_P.

The second fuse information storage 364 of the fuse information storage 360 may receive the second fuse data FDATA_BK13 programmed in the second fuse circuit and the second bank target row address ATROW_BK13<0:14>. Herein, the second fuse data FDATA_BK13 may include 64 data. When the fuse enable signal of the first fuse data FDATA_BK13 is enabled and at the same time the repair address of the first fuse data FDATA_BK13 coincides with the second bank target row address ATROW_BK13<0:14>, the second fuse information storage 364 may maintain the first fuse line FL0 at the precharge state, that is, the power source voltage VDD level, and drive the remaining second to 64^{th} fuse lines FL1 to FL63 with the ground voltage level.

As a result, the second repair controller 374 of the repair control circuit 370 may enable and output a second bank repair activation signal TXRED_BK13, and may map the repair control signal RP_CTRL<0:5> of ‘000000’ (not shown) to the second bank target row address ATROW_BK13<0:14> and output it.

The second output selector 334 may output the second bank repair activation signal TXRED_BK13 transferred from the second repair controller 374 and the second bank target row address ATROW_BK13<0:14> in response to the second row active level signal RACT13_L.

As a result, the output latch 339 may latch the second bank repair activation signal TXRED_BK13 and the second bank target row address ATROW_BK13<0:14> and output them as the final post-repair activation signal TXRED and the final target row address ATROWD.

According to the embodiments of the present invention described above, the memory array region is disposed in the core region, and the fuse latch circuit and the fuse circuit for programming the repair information are disposed in the peripheral circuit region, and the repair information stored in the fuse latch circuit is transferred to the core region through the existing address line. Therefore, the semiconductor memory device may have a lower density in the core region and an increased area efficiency by distributively disposing the fuse circuit and the fuse latch circuit in a peripheral circuit region.

Additionally, the semiconductor memory device according to the embodiments of the present invention may be guaranteed with the reliability of repair information that is stored for a repair operation while maximally using the existing circuits without additionally requiring a circuit, by transferring the repair information from a peripheral circuit region to a core region through an existing address line.

Furthermore, the semiconductor memory device according to the embodiments of the present invention may attain a timing margin by disposing a fuse latch unit in a peripheral circuit region. With a conventional any-to-any redundancy scheme, the timing margin is low since latch circuits disposed in a core region are serially positioned on one side of the core region.

While the present invention has been described with respect to the specific embodiments, it will be apparent to those skilled in the art that various changes and modifications may be made without departing from the spirit and scope of the invention as defined in the following claims.

For example, logical gates and transistors described in the above-described embodiments of the present invention may have different positions and types according to the polarity of an input signal. Also, although a row repair operation is described in the above embodiments of the present invention, the technology of the present invention may be applied to a column operation as well.

What is claimed is:

1. A semiconductor memory device comprising:
a memory array region including normal memory cells and redundant memory cells which replace repair target memory cells;
a fuse circuit including fuse cells for programming repair addresses of the repair target memory cells, suitable for outputting fuse data including the programmed repair addresses and fuse enable signals indicating whether or not the repair addresses are valid, in response to a boot-up signal;
a fuse information storage including N latch circuits for storing the fuse data, wherein each of the N latch circuits drives fuse lines assigned from N fuse lines based on the fuse enable signals and a comparison result of the corresponding repair addresses and an input address; and
a repair control circuit suitable for generating a repair activation signal and an M-bit repair control signal based on signals of the N fuse lines, M being a positive integer smaller than N, and outputting the M-bit repair control signal to multiple address lines by selectively mapping the M-bit repair control signal to some bits of the input address, based on the repair activation signal.

2. The semiconductor memory device of claim 1, wherein the memory array region is disposed in a core region, and the fuse circuit, the fuse information storage, and the repair control circuit are disposed in a peripheral circuit region.

3. The semiconductor memory device of claim 1, wherein M is a least integer among positive integers that are equal to or greater than log₂N.

4. The semiconductor memory device of claim 1, wherein the fuse information storage drives the N fuse lines with a ground voltage level when the fuse enable signals are disabled or the input address does not coincide with the repair addresses stored in the N latch circuits, and
the repair control circuit disables the repair activation signal and outputs the input address to the multiple address lines without mapping the M-bit repair control signal to the some bits of the input address.

5. The semiconductor memory device of claim 1, wherein when a K^{th} fuse enable signal stored in a K^{th} latch circuit among the N latch circuits is enabled and the input address coincides with a K^{th} repair address, the fuse information storage drives a K^{th} fuse line with a voltage level higher than a ground voltage level while driving the remaining fuse lines with the ground voltage level, and
the repair control circuit enables the repair activation signal, and outputs the M-bit repair control signal to the multiple address lines by mapping the M-bit repair control signal corresponding to the K^{th} repair address to the some bits of the input address.

6. The semiconductor memory device of claim 1, further comprising:
a first ground line provided to the fuse information storage; and
a second ground line provided to the repair control circuit,
wherein the ground voltage is supplied to the second ground line after the ground voltage is supplied to the first ground line.

7. The semiconductor memory device of claim 1, wherein the fuse information storage includes:
a fuse latch including the N latch circuits which correspond to the N fuse lines in 1:1, for individually storing the fuse data outputted from the fuse circuit, and driving the fuse lines assigned thereto based on the fuse enable signal of the fuse data and the comparison result of the repair address of the fuse data and the input address;
a precharger suitable for precharging the N fuse lines with a predetermined voltage level in response to an initialization signal; and
an output latch suitable for latching the signals of the N fuse lines.

8. The semiconductor memory device of claim 7, wherein each of the N latch circuits includes:
a fuse enable latch suitable for receiving the fuse enable signal and driving a corresponding fuse line; and
a plurality of address latches suitable for driving the corresponding fuse line by comparing the repair address with the input address.

9. The semiconductor memory device of claim 1, wherein the repair control circuit includes:
an encoder suitable for generating the repair activation signal and the M-bit repair control signal by encoding the signals of the N fuse lines and respectively outputting the repair activation signal and the M-bit repair control signal to first to (M+1)^{th} output lines; and
an address mapper suitable for mapping the M-bit repair control signal to the some bits of the input address in response to the repair activation signal.

10. The semiconductor memory device of claim 9, wherein the repair control circuit includes:
a precharger suitable for precharging the first to (M+1)^{th} output lines with a predetermined voltage level in response to the initialization signal; and
an output latch suitable for latching and outputting signals of the first to (M+1)^{th} output lines.

11. The semiconductor memory device of claim 9, wherein the encoder includes:
a first encoding unit including N unit switches which are coupled in parallel between the first output line and a ground line and respectively turned on in response to the signals of the N fuse lines; and
M second encoding units each of which includes L unit switches which are coupled in parallel between the second to (M+1)^{th} output lines and the ground line, where L is a least integer among positive integers that are equal to or greater than N/2.

12. The semiconductor memory device of claim 9, wherein the address mapper includes:
a first transfer unit for, when the repair activation signal is enabled, transferring the M-bit repair control signal transferred through the second to (M+1)^{th} output lines through a portion of the multiple address lines; and
a second transfer unit for, when the repair activation signal is disabled, transferring the input address through the multiple address lines.

13. The semiconductor memory device of claim 1, further comprising:
a row circuit suitable for enabling a normal word line corresponding to a row address of the input address in response to a row active signal, and when the repair activation signal is enabled, enabling a redundant word line that is designated by the repair control signal;
a column circuit suitable for selecting a particular bit line by decoding a column address of the input address; and
a data input/output circuit suitable for outputting data transferred from the selected bit line to an input/output pad in response to a read signal, and transferring and storing data inputted through the input/output pad to the selected bit line in response to a write signal.

14. A semiconductor memory device comprising:
a plurality of fuse information storages, each corresponding to at least one of a plurality of memory banks and including N latch circuits for storing fuse data transferred from a fuse circuit during a boot-up operation, wherein the N latch circuits drive fuse lines assigned from N fuse lines based on fuse enable signals of the fuse data and a comparison result of repair addresses of the fuse data and an input address;
a plurality of repair controllers corresponding to the fuse information storages, wherein each of the repair controllers generates a repair activation signal and an M-bit repair control signal, M being a positive integer smaller than N based on signals of the N fuse lines, and outputting the M-bit repair control signal by selectively mapping the M-bit repair control signal to some bits of the input address based on the repair activation signal;
an input controller suitable for selectively transferring the input address to one of the plurality of the fuse information storages in response to a row active signal; and
an output controller suitable for selecting data outputted from the plurality of the repair controllers and outputting the selected data to multiple address lines in response to the row active signal.

15. The semiconductor memory device of claim 14, further comprising:
a memory array region including the plurality of the memory banks, each including normal memory cells and redundant memory cells which replace repair target memory cells; and
a plurality of fuse circuits including fuse cells for programming repair addresses of the repair target memory cells, suitable for outputting the fuse data which include the repair addresses programmed in the fuse cells and the fuse enable signals informing whether or not the repair addresses are valid, in response to a boot-up signal,
wherein the memory array region is disposed in a core region, and the plurality of the fuse circuits, the plurality of the fuse information storages and the plurality of the repair controllers are disposed in a peripheral circuit region.

16. The semiconductor memory device of claim 14, wherein M is a least integer among positive integers that are equal to or greater than log₂N.

17. The semiconductor memory device of claim 14, wherein each of the plurality of the fuse information storages drives the N fuse lines with a ground voltage level when the fuse enable signals are disabled or the input address does not coincide with the repair addresses stored in the N latch circuits, and
the repair controller disables the repair activation signal and outputs the input address without mapping the M-bit repair control signal to the some bits of the input address.

18. The semiconductor memory device of claim 14, wherein when a K^{th} fuse enable signal stored in a K^{th} latch circuit among the N latch circuits is enabled and the input address coincides with a K^{th} repair address, each of the plurality of the fuse information storages drives a K^{th} fuse line with a voltage level that is higher than the ground voltage level while driving the remaining fuse lines with the ground voltage level, and
the repair controller enables the repair activation signal, and
outputs the M-bit repair control signal by mapping the M-bit repair control signal corresponding to the K^{th} repair address to the some bits of the input address.

19. The semiconductor memory device of claim 14, further comprising:
a first ground line provided to the plurality of the fuse information storages; and
a second ground line provided to the plurality of the repair controllers,
wherein the ground voltage is supplied to the second ground line after the ground voltage is supplied to the first ground line.
